(19) United States
(12) Patent Application Publication
(10) Pub. No.: US 2015/0214438 A1
(43) Pub. Date: Jul. 30, 2015

(54) LED MODULE AND METHOD FOR MANUFACTURING THE SAME

(71) Applicant: WISETOP TECHNOLOGY CO., LTD., HSINCHU CITY (TW)

(72) Inventors: WEI-CHEN LIANG, HSINCHU COUNTY (TW); PIN CHANG, HSINCHU CITY (TW)

(21) Appl. No.: 14/255,020

(22) Filed: Apr. 17, 2014

(30) Foreign Application Priority Data
Jan. 24, 2014 (TW) 103102655

(51) Int. Cl. H01L 33/44; H01L 33/64; H01L 33/60; H01L 33/50; H01L 27/15; H01L 33/62

(52) U.S. Cl. CPC H01L 33/44; H01L 27/15; H01L 33/62; H01L 33/60; H01L 33/50; H01L 33/647

(57) ABSTRACT

An LED module and method for manufacturing the same are disclosed. The LED module of the present invention comprises a substrate, at least one LED chip, and a buffer layer. The LED chip is disposed on the predetermined position of the top surface of the substrate. The buffer layer is disposed on the top surface of the substrate and covers the LED chip. The buffer layer comprises at least one opening disposed on the top electrode of the LED chip. At least one contact pad is disposed in the opening and electrically coupled to the top electrode. Furthermore, a conductive pattern layer is disposed on the buffer layer and electrically coupled to the contact pad.

### FIELD OF THE INVENTION

The present invention relates to an LED module, and particularly to an LED module with high reliability, high heat dissipation efficiency, and variety of application purposes and method for manufacturing the same.

### BACKGROUND OF THE INVENTION

Referring to FIG. 1, there is shown a schematic diagram of an LED module 10 according to the prior art. The LED module 10 comprises a substrate 12 with circuit pattern 14 formed on the top surface, a plurality of LED chips 16 disposed on the predetermined position of the substrate 12, and a plurality of bonding wires 18 connecting the electrodes 161 of the LED chips to the circuit pattern 14.

In general, there is a sapphire substrate between the light emitting layer of the LED chip 16 and the substrate 12. The thermal conductivity of the sapphire substrate is poor. The diameter of the bonding wire 18 is very small. It is difficult for the heat generated by the LED chip 16 to propagate from the bonding wire 18 and dissipates.

The circuit pattern 14 is disposed on the top surface of the substrate 12 and the light emitting layer of the LED chip 16 is usually at the top portion of the LED chip 16. If the LED module 10 is configured to emit light downward, the circuit pattern 14 shadows a portion of light. If the LED module 10 is configured to emit light upward, the electrodes 161 of the LED chip 16 shadows a portion of light. In other words, the conventional LED module 10 is inefficiency.

### SUMMARY OF THE PRESENT INVENTION

It is an objective of the present invention to provide an LED module, and particularly an LED module with high reliability, high heat dissipation efficiency, and variety of application purposes and method for manufacturing the same.

It is another objective of the present invention to provide an LED module with a buffer layer to smooth the surface for improving the reliability of the conductive pattern layer.

It is still another objective of the present invention to provide an LED module, wherein the heat dissipation layer is close to the light emitting layer of the LED chip for enhancing heat dissipation efficiency.

It is one objective of the present invention to provide an LED module, wherein the conductive pattern layer is disposed at the same side of the module with the electrode of the LED chip for enhancing the light emitting efficiency.

It is one objective of the present invention to provide a method for manufacturing the LED module for reducing the steps of manufacturing processes and the cost for producing the LED module.

The present invention provides an LED module, comprising: a substrate having a top surface; at least one LED chip disposed on the top surface of the substrate, wherein each LED chip has two electrodes and at least one of the electrodes is atop electrode disposed on the top of the LED chip; a buffer layer disposed on the top surface of the substrate and covering the at least one LED chip, wherein the buffer layer comprises at least one opening disposed on the top electrode; at least one contact pad disposed in the opening and electrically coupled to the top electrode.

In one embodiment of the present invention, the LED module further comprises a conductive pattern layer disposed on the buffer layer and electrically coupled to the contact pad.

In one embodiment of the present invention, the LED module further comprises a reflective layer disposed on the buffer layer.

In one embodiment of the present invention, the LED module further comprises a phosphor layer selectively disposed between the top surface of substrate and the LED chip or on the bottom surface of the substrate.

In one embodiment of the present invention, the buffer layer comprises at least one dam-shaped structure disposed adjacent to the LED chip.

In one embodiment of the present invention, the buffer layer further comprises at least one filler disposed between the dam-shaped structure and the LED chip, wherein the filler is wrapped around the LED chip and has at least one opening disposed on the top electrode of the LED chip.

In one embodiment of the present invention, the filler comprises at least one phosphor.

In one embodiment of the present invention, the buffer layer is selectively formed by one process of coating, screen printing, imprinting, transfer printing, jet printing, spin coating, injection molding, or the combination thereof.

In one embodiment of the present invention, the LED module further comprises at least one spacer disposed selectively on the top surface of the substrate or the LED chip.

In one embodiment of the present invention, wherein the dam-shaped structure is selectively formed by one process of screen printing, imprinting, transfer printing, jet printing, etching, molding, die casting, injection molding, or the combination thereof.

In one embodiment of the present invention, the substrate is selectively made of one of glass, polycarbonate (PC), acrylics, or the combination thereof.

In one embodiment of the present invention, wherein the buffer layer is selectively formed by one of spin on glass (SOG), photoresist, acrylics, silicone, or the combination thereof.

In one embodiment of the present invention, the phosphor layer comprises one of a yellow phosphor, a green phosphor, a red phosphor, or the combination thereof.

In one embodiment of the present invention, reflective layer is selectively formed by one of metal, alloy, metallic oxide, multi-layer optical reflective film, or the combination thereof.

In one embodiment of the present invention, the conductive pattern layer is selectively formed by one of metal, conductive adhesives, transparent conductive metal oxide, conductive polymers, or the combination thereof.

In one embodiment of the present invention, the buffer layer further comprises at least one phosphor.

In one embodiment of the present invention, the LED module further comprises two module contacts.

In one embodiment of the present invention, the module contacts are selectively disposed on one of the top surface of the substrate, the bottom surface of the substrate, the conductive pattern layer, or the sidewall of the module.

In one embodiment of the present invention, the buffer layer comprises at least one dome structure for covering the at least one LED chip.

In one embodiment of the present invention, the dome structure is selectively formed by one process of screen printing, jet printing, transfer printing, exposing, heat softening, or the combination thereof.

In one embodiment of the present invention, the LED module further comprises a reflective layer disposed on the dome structure.

In one embodiment of the present invention, the substrate comprises selectively one of a lens structure, an optical grating structure, a Fresnel lens structure, or the combination thereof.

The present invention further provides a method for manufacturing an LED module, comprising: providing a substrate having a top surface; providing at least one LED chip, wherein the LED chip has two electrodes and at least one of the electrodes is a top electrode disposed on the top of the LED chip, wherein each top electrode is disposed with a contact pad; disposing each LED chip on a predetermined position of the top surface of the substrate; forming a buffer layer to cover the at least one LED chip; and removing a top portion of the buffer layer to expose the contact pad.

In one embodiment of the present invention, the buffer layer comprises at least one dime structure, each dome structure covers one of the at least one LED chip.

In one embodiment of the present invention, the method further comprises a step of forming a reflective layer on the buffer layer before the step of removing the top portion of the buffer layer.

### BRIEF DESCRIPTION OF THE DRAWINGS

FIG. 1 is schematic cross-sectional view of an LED module according to the prior art.

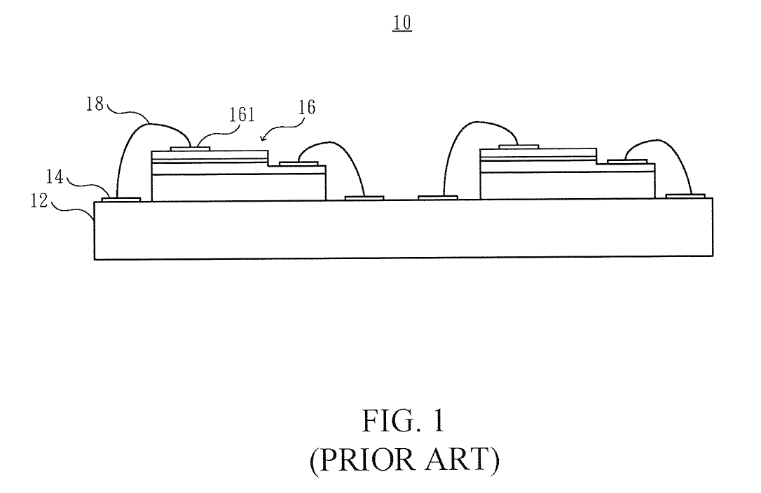

FIG. 2 is a schematic cross-sectional view of an LED module in accordance with one embodiment of the present invention.

FIG. 3 is a schematic cross-sectional view of an LED module in accordance with another embodiment of the present invention.

FIG. 4 is a schematic cross-sectional view of an LED module in accordance with one embodiment of the present invention.

FIG. 5 is a schematic cross-sectional view of an LED module in accordance with one embodiment of the present invention.

FIG. 6 is a schematic cross-sectional view of an LED module in accordance with one embodiment of the present invention.

### DETAILED DESCRIPTION OF THE PREFERRED EMBODIMENTS

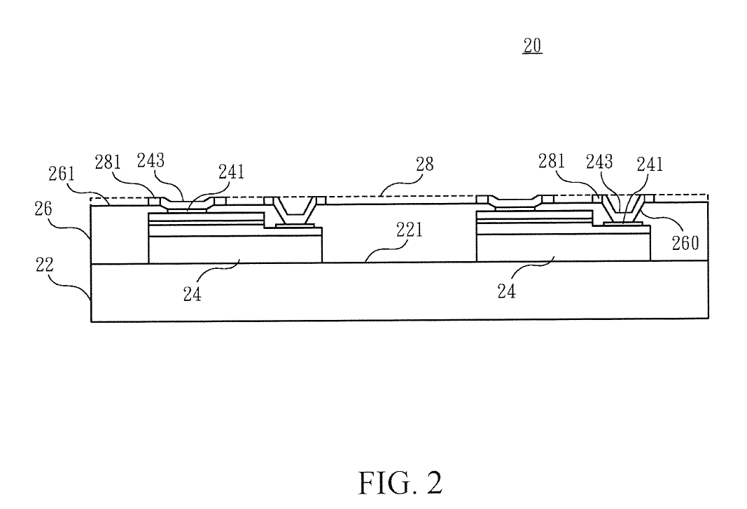

Referring to FIG. 2, a schematic cross-sectional view of an LED module in accordance with one embodiment of the present invention is illustrated. In the present embodiment, the LED module 20 comprises a transparent substrate 22, at least one LED chip 24, a buffer layer 26, and a conductive pattern layer 28.

The at least one LED chip 24 is disposed on the predetermined position of the top surface 221 of the substrate 22. Each LED chip 24 comprises two electrodes 241 wherein at least one of the electrodes 241 is atop electrode 241 disposed on the top of the LED chip 24.

The buffer layer 26 is disposed on the top surface 221 of the substrate 22 and covers the at least one LED chip 24. The buffer layer 26 comprises at least one opening 260 disposed on the top electrode 241 of the LED chip 24. In one embodiment of the present invention, at least one contact pad 243 is disposed in the opening 260 and is electrically connected to the top electrode 241. The conductive pattern layer 28 is formed on the buffer layer 26. The conductive pattern layer 28 comprises the circuit 281 of the module 20 and is connected to the top electrode 241 of the LED chip 24 by the contact pad 243.

In the present invention, the conductive pattern layer 28 is formed on the buffer layer 26, the electric reliability is improved. The conductive pattern layer 28 is closely connected to the top electrode 241 of the LED chip 24, that the heat generated by the LED chip 24 is easily propagated to the conductive pattern layer 28 and is easily dissipated because of the large surface of the conductive pattern layer 28. The heat dissipation efficiency is greatly enhanced.

In one embodiment of the present invention, the buffer layer 26 is selectively formed by one process of coating, screen printing, imprinting, transfer printing, jet printing, spin coating, or the combination thereof.

In one embodiment of the present invention, the contact pad 243 is integrated with the conductive pattern layer 28.

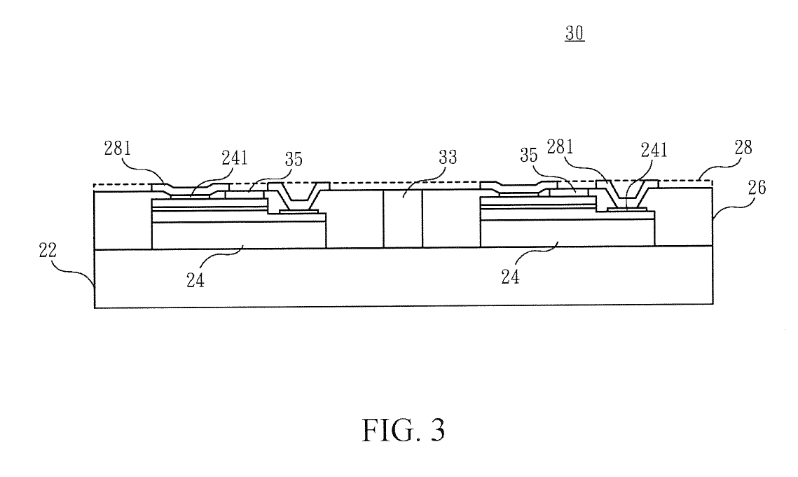

Referring to FIG. 3, a schematic cross-sectional view of an LED module in accordance with another embodiment of the present invention is illustrated. In the present embodiment, the structure of the LED module 30 is substantially the same as the embodiment shown in FIG. 2, wherein the LED module 30 of the present embodiment comprises at least one spacer 33, 35.

The spacer 33, 35 is selectively disposed on the top surface 221 of the substrate 22 or the LED chip 24. By using the spacer 33, 35, the thickness of the buffer layer 26 is determined. After the spacer 33, 35 is disposed, a mold (not shown) is used to cover the substrate 22 and the LED chip 24, and the buffer layer 26 is formed by injection molding process.

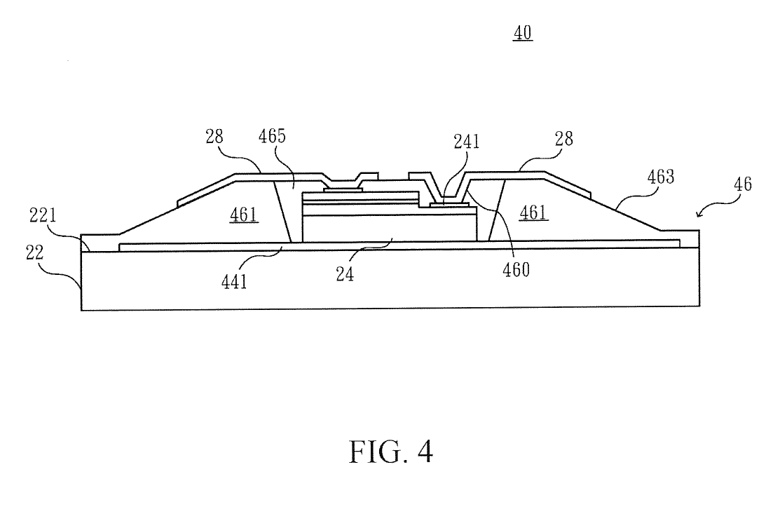

Referring to FIG. 4, a schematic cross-sectional view of an LED module in accordance with one embodiment of the present invention is illustrated. In the present embodiment, the structure of the LED module 40 is substantially the same as the embodiment shown in FIG. 2, wherein the buffer layer 46 of the LED module 40 comprises at least one dam-shaped structure 461 disposed adjacent to the LED chip 24.

The dam-shaped structures 461 can be disposed around each LED chip 24, or adjacent to one or two sides of the LED chip 24. In one embodiment of the present invention, a dam-shaped structure 461 is disposed adjacent to a plurality of LED chips 24 in the same column or in the same row.

In one embodiment of the present invention, a filler 465 is disposed between the LED chip 24 and the dam-shaped structure 461. The filler 465 is wrapped around the LED chip 24 and has at least one opening 460 disposed on the top electrode 241 of the LED chip 24.

In the present embodiment, the buffer layer 46 with the dam-shaped structure 461 and the filler 465 has a continuous and smooth top surface 463 to improve the reliability of the conductive pattern layer 28.

In one embodiment of the present invention, the dam-shaped structure 461 is selectively formed by one process of screen printing, imprinting, transfer printing, jet printing, etching, die casting, injection molding, or the combination thereof.

In one embodiment of the present invention, the LED module 40 of the present invention further comprises a phosphor layer 441 disposed selectively between the top surface 221 of substrate 22 and the LED chip 24 or on the bottom surface of the substrate 22.

In one embodiment of the present invention, the filler 465 comprises at least one phosphor.

In one embodiment of the present invention, the substrate 22 is selectively made of one of glass, polycarbonate (PC), acrylics, or the combination thereof.

In one embodiment of the present invention, the phosphor is selectively one of a yellow phosphor, a green phosphor, a red phosphor, or the combination thereof.

In one embodiment of the present invention, a reflective layer (28) is disposed on the top surface 463 of the buffer layer 46.

In one embodiment of the present invention, the reflective layer is selectively formed by one of metal, alloy, metallic oxide, multi-layer optical reflective film, or the combination thereof.

In one embodiment of the present invention, the conductive pattern layer 28 is selectively formed by one of metal, conductive adhesives, transparent conductive metal oxide (such as ITO and AZO), conductive polymers (such as PEDOT:PSS), or the combination thereof.

In one embodiment of the present invention, the reflective layer is integrated with the conductive pattern layer 28.

In one embodiment of the present invention, the buffer layer 26, 46 is selectively formed by one of spin on glass (SOG), photoresist, acrylics, silicone, or the combination thereof. In one embodiment of the present invention, the buffer layer 26, 46 further comprises one of diamond powder, alumina powder, zinc oxide powder, carbon nanotube powder, metal, or the combination thereof for adjusting the optical or thermal properties of the buffer layer 26, 46.

In one embodiment of the present invention, the buffer layer 26, 46 further comprises at least one phosphor.

In one embodiment of the present invention, the thermal dissipation layer, the reflective layer and the conductive pattern layer are independently embodied. In another embodiment of the present invention, two or all of them are integrated.

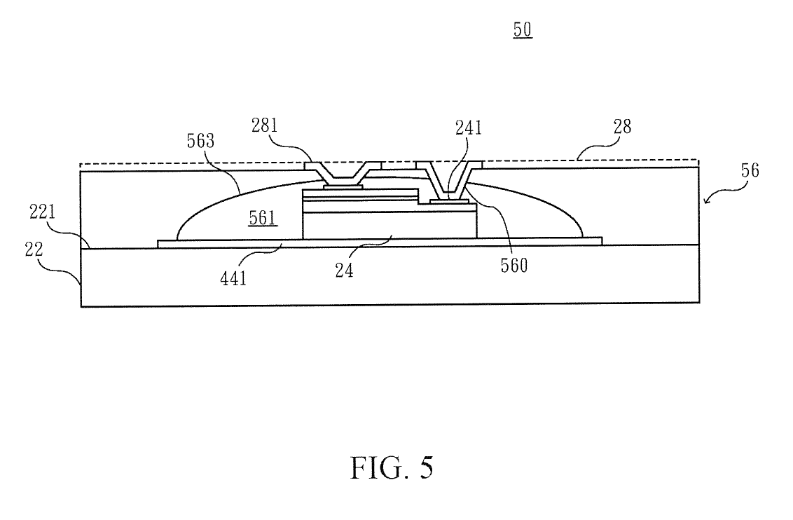

Referring to FIG. 5, a schematic cross-sectional view of an LED module in accordance with one embodiment of the present invention is illustrated. In the present embodiment, the structure of the LED module 50 is substantially the same as the embodiment shown in FIG. 2, wherein the buffer layer 56 of the LED module 50 comprises at least one dome structure 561 for covering the at least one LED chip 24.

The dome structure 561 is selectively formed by one process of screen printing, jet printing, transfer printing, exposing, heat softening, or the combination thereof.

In one embodiment of the present invention, the buffer layer 56 comprises at least one opening 560 disposed on the top electrode 241 of the LED chip 24. The conductive pattern layer 28 is connected to the top electrode 241 of the LED chip 24 at the opening 560.

In one embodiment of the present invention, a reflective layer (not shown) is disposed on the top surface 563 of the dome structure 561.

In one embodiment of the present invention, the LED module 20, 30, 40, and 50 further comprises two module contacts (not shown) for connecting to an application circuit.

In one embodiment of the present invention, the module contacts are selectively disposed on one of the top surface 221 of the substrate 22, the bottom surface of the substrate 22, the conductive pattern layer 28, or the sidewall of the LED module.

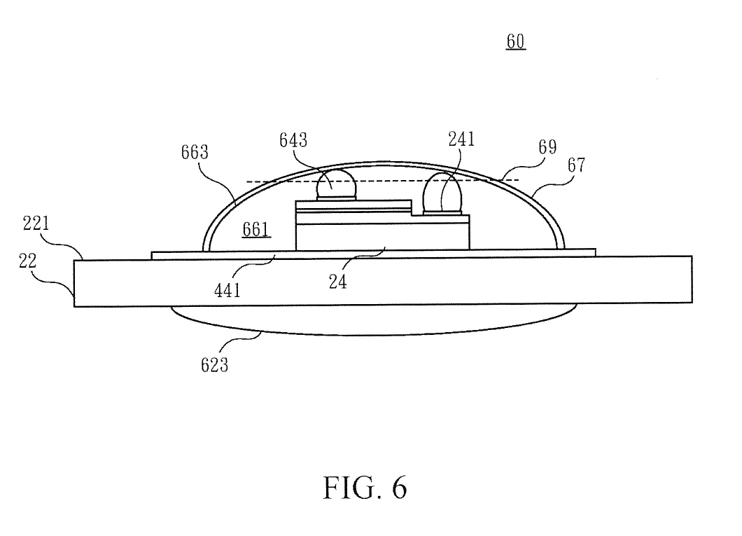

Referring to FIG. 6, a schematic cross-sectional view of an LED module in accordance with one embodiment of the present invention is illustrated. In the present embodiment, the structure of the LED module 60 is substantially the same as the embodiment shown in FIG. 5, wherein the buffer layer comprises at least one dome structure 661, each dome structure 661 covers one of the at least one LED chip 24. The method for manufacturing the LED module 60 comprises the following steps. Firstly provide the substrate 22 and the at least one LED chip 24, wherein the substrate 22 has a top surface 221, each LED chip 24 has two electrodes and at least one of the electrodes is a top electrode 241, wherein each top electrode 241 is disposed with a contact pad 643.

Dispose the at least one LED chip 24 on the predetermined position of the top surface 221 of the substrate 22 and form a buffer layer (661) to cover the at least one LED chip 24. Finally remove the top portion of the buffer layer (661) according to the dotted line 69. Then the structure of the opening 660 is formed and the contact pad 643 is exposed.

In one embodiment of the present invention, the buffer layer comprises at least one dome structure 661, each dome structure 661 covers one of the at least one LED chip 24.

In one embodiment of the present invention, a reflective layer 69 is formed on the top surface 663 of the dome structure 661 before the top portion of the dome structure 661 is removed.

In one embodiment of the present invention, a phosphor layer 441 is disposed selectively between the top surface 221 of the substrate 22 and the LED chip 24 or on the bottom surface of the substrate 22.

In one embodiment of the present invention, the substrate 22 selectively comprises one of a lens structure 623, an optical grating structure, a Fresnel lens structure, or the combination thereof.

In one embodiment of the present invention, the substrate 22 is a flexible substrate.

By using the structure of the present invention, the reliability and heat dissipation efficiency of the LED module are improved, and a variety of application purposes of the LED module is provided.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. An LED module, comprising:
a substrate having a top surface;
at least one LED chip disposed on the top surface of the substrate, wherein each LED chip has two electrodes and at least one of the electrodes is a top electrode disposed on the top of the LED chip;
a buffer layer disposed on the top surface of the substrate and covering the at least one LED chip, wherein the buffer layer comprises at least one opening disposed on the top electrode; and
at least one contact pad disposed in the opening and electrically coupled to the top electrode.

2. The LED module as claimed in claim 1, further comprising a conductive pattern layer disposed on the buffer layer and electrically coupled to the contact pad.

3. The LED module as claimed in claim 1, further comprising a reflective layer disposed on the buffer layer.

4. The LED module as claimed in claim 1, further comprising a phosphor layer selectively disposed between the top surface of substrate and the LED chip or on the bottom surface of the substrate.

5. The LED module as claimed in claim 1, wherein the buffer layer comprises at least one dam-shaped structure disposed adjacent to the LED chip.

6. The LED module as claimed in claim 5, wherein the buffer layer further comprises at least one filler disposed between the dam-shaped structure and the LED chip, wherein the filler is wrapped around the LED chip and has at least one opening disposed on the top electrode of the LED chip.

7. The LED module as claimed in claim 6, wherein the filler comprises at least one phosphor.

8. The LED module as claimed in claim 1, wherein the buffer layer is selectively formed by one process of coating, screen printing, imprinting, transfer printing, jet printing, spin coating, injection molding, or the combination thereof.

9. The LED module as claimed in claim 1, further comprising at least one spacer disposed selectively on the top surface of the substrate or the LED chip.

10. The LED module as claimed in claim 5, wherein the dam-shaped structure is selectively formed by one process of screen printing, imprinting, transfer printing, jet printing, etching, molding, die casting, injection molding, or the combination thereof.

11. The LED module as claimed in claim 1, wherein the substrate is selectively made of one of glass, polycarbonate (PC), acrylics, or the combination thereof.

12. The LED module as claimed in claim 1, wherein the buffer layer is selectively formed by one of spin on glass (SOG), photoresist, acrylics, silicone, or the combination thereof.

13. The LED module as claimed in claim 4, wherein the phosphor layer comprises one of a yellow phosphor, a green phosphor, a red phosphor, or the combination thereof.

14. The LED module as claimed in claim 3, wherein reflective layer is selectively formed by one of metal, alloy, metallic oxide, multi-layer optical reflective film, or the combination thereof.

15. The LED module as claimed in claim 2, wherein the conductive pattern layer is selectively formed by one of metal, conductive adhesives, transparent conductive metal oxide, conductive polymers, or the combination thereof.

16. The LED module as claimed in claim 1, wherein the buffer layer further comprises at least one phosphor.

17. The LED module as claimed in claim 2, further comprising two module contacts.

18. The LED module as claimed in claim 17, wherein the module contacts are selectively disposed on one of the top surface of the substrate, the bottom surface of the substrate, the conductive pattern layer, or the sidewall of the module.

19. The LED module as claimed in claim 1, wherein the buffer layer comprises at least one dome structure for covering the at least one LED chip.

20. The LED module as claimed in claim 19, wherein the dome structure is selectively formed by one process of screen printing, jet printing, transfer printing, exposing, heat softening, or the combination thereof.

21. The LED module as claimed in claim 19, further comprising a reflective layer disposed on the dome structure.

22. The LED module as claimed in claim 1, wherein the substrate comprises selectively one of a lens structure, an optical grating structure, a Fresnel lens structure, or the combination thereof.

23. A method for manufacturing an LED module, comprising:
providing a substrate having a top surface;
providing at least one LED chip, wherein each LED chip has two electrodes and at least one of the electrodes is a top electrode disposed on the top of the LED chip, wherein each top electrode is disposed with a contact pad;
disposing each LED chip on a predetermined position of the top surface of the substrate;
forming a buffer layer to cover the at least one LED chip; and
removing a top portion of the buffer layer to expose the contact pad.

24. The method as claimed in claim 23, wherein the buffer layer comprises at least one dome structure, each dome structure covers one of the at least one LED chip.

25. The method as claimed in claim 24, further comprising a step of forming a reflective layer on the buffer layer before the step of removing the top portion of the buffer layer.
